(19) United States
(12) Patent Application Publication
(10) Pub. No.: US 2025/0266288 A1
(43) Pub. Date: Aug. 21, 2025

(54) SUSCEPTOR FOR EPITAXIAL GROWTH AND EPITAXIAL GROWTH APPARATUS INCLUDING THE SAME

(71) Applicant: SK SILTRON CO., LTD., Gumi-si (KR)

(72) Inventors: Yong Jin KIM, Gumi-si (KR); Young Su KU, Gumi-si (KR)

(21) Appl. No.: 19/054,500

(22) Filed: Feb. 14, 2025

(30) Foreign Application Priority Data
Feb. 20, 2024 (KR) 10-2024-0024144

(51) Int. Cl. H01L 21/687; C23C 16/458; C30B 25/12

(52) U.S. Cl. CPC H01L 21/68785; C23C 16/4584; C30B 25/12

(57) ABSTRACT

Provided are a susceptor for epitaxial growth, which is capable of forming a thin film having an uniform thickness through upper temperature uniformization of a wafer, and an epitaxial growth apparatus including the same. A susceptor for an epitaxial growth apparatus includes a body provided with a pocket, in which a wafer is seated, on a top surface thereof, and a temperature control plate seated in the pocket and having a plate shape in which the wafer is supported on a top surface thereof. The temperature control plate has a plurality of hollows.

### CROSS-REFERENCE TO RELATED APPLICATIONS

The present application claims priority under 35 U.S.C. 119 and 35 U.S.C. 365 to Korean Patent Application No. 10-2024-0024144 (filed on Feb. 20, 2024), which is hereby incorporated by reference in its entirety.

### BACKGROUND

The present disclosure relates to a susceptor for epitaxial growth, which is capable of forming a thin film having an uniform thickness through upper temperature uniformization of a wafer, and an epitaxial growth apparatus including the same.

In general, a wafer widely used as a material for manufacturing semiconductor elements refers to a single crystal silicon thin plate made of polycrystalline silicon as a raw material, as well as a sapphire substrate, a compound substrate, and an SiC substrate.

The single crystal silicon wafer may be formed through a slicing process of growing polycrystalline silicon into a single crystal silicon ingot and then slicing the silicon ingot into the form of a wafer, a lapping process of uniformizing a thickness of the wafer to form a flat wafer, an etching process of removing or alleviating damage caused by sequential polishing, and a polishing process of polishing a surface of the wafer, and a cleaning process of cleaning the wafer.

In addition, many epitaxial wafers are manufactured by growing another single crystal film, i.e., an epi layer on the polished surface of the wafer. The epi layer has high purity and excellent crystal characteristics, and thus, each epitaxial wafer may have an advantage in improving yield and element characteristics in a semiconductor device that is becoming increasingly integrated.

Referring to the process of depositing the epi layer on the surface of the wafer, the silicon wafer is mounted on a single susceptor that is horizontally disposed within a process chamber, and the wafer is raised to a high temperature using a heat source such as an infrared lamp disposed around the wafer, and then, a reactive gas flows over the surface of the wafer at the high temperature while the susceptor rotates so that the epitaxial growth on the surface of the wafer begins.

As a diameter of the wafer has recently become larger, a fluid flow within the process chamber and a shape of the susceptor are important in order to uniformly form the epitaxial layer up to an edge of the wafer.

FIG. 1 is a side view illustrating a support structure of a susceptor for epitaxial growth according to the related art, FIG. 2 is a graph illustrating a change in thickness of a thin film depending on a growth temperature of the thin film during an epitaxial growth process according to the related art, and FIG. 3 is a graph illustrating a change in thickness of the thin film within a radius of the wafer during the epitaxial growth process according to the related art.

According to the related art, as illustrated in FIG. 1, a susceptor 11 on which a silicon wafer is seated, a rotational shaft 12 disposed below the susceptor 11, and a supporter 13 mounted on an upper end of the rotational shaft 12 to support the susceptor 11 may be provided.

The susceptor 11 may be provided with a pocket (not shown) in which the wafer is seated and may rotate in a state of being supported by the supporter 13. When the reactive gas flows over the susceptor 11, a thin film may be grown on a top surface of the wafer seated on the susceptor 11.

As the epitaxial growth process progresses, as illustrated in FIG. 2, the higher a temperature at an upper portion of the wafer, the thicker the thin film is formed.

However, the wafer having a diameter of about 150 mm or more is divided into four areas in a radial direction, and a change in thickness of the thin film within a radius of the wafer during the epitaxial growth process is measured. As illustrated in FIG. 3, a thickness deviation of the thin film within the radius of the wafer is about 0.4 um, and thickness of the thin film from a center of the wafer to the first to third areas becomes thicker, and then the thickness of the thin film in the fourth area rapidly becomes thinner.

When considering the formed thickness of the thin film according to the related art, since the thickness in the first area is thinner than that in the third area, it is seen that the temperature in the first area is less than that in the third area. Thus, it is seen that the thin film formation temperatures in the first to fourth areas are unbalanced.

According to Japanese Patent Laid-Open No. 2007-294942 (filed on Mar. 30, 2007), this document relates to an apparatus for manufacturing an epitaxial wafer, which controls a thickness of an epitaxial layer on an outer circumferential portion of the wafer. The apparatus may be provided with a pocket having an opening in which the semiconductor wafer is disposed, include a susceptor that fixes the semiconductor wafer, be provided with an orientation-dependent control means that depends on a crystal orientation of the semiconductor wafer and/or an orientation-independent control means that does not depend on the crystal orientation of the semiconductor wafer, and improve flatness of a circumferential portion of the semiconductor wafer.

According to the above-described technologies, a structure and shape of the susceptor may be periodically changed according to the change in crystal orientation of the wafer to control a thickness of the thin film. However, it is difficult to manufacture the susceptor, and there is a limitation that an effect is insufficient when a thickness deviation of the thin film is large.

According to Korean Patent Publication No. 2019-0100365 (priority application date: Mar. 7, 2017), this document relates to an epitaxial growth apparatus for improving uniformity of a thickness of an epitaxial layer. The epitaxial growth apparatus may be provided with a susceptor 20, a preheat ring 60 that covers a side surface of the susceptor 20 with a gap therebetween. Here, a gap width that is wider than a gap width W1 between the susceptor 20 and the preheat ring 60 at a side of a reactive gas supply port is defined in at least a portion between the susceptor 20 and the preheat ring 60.

According to the above-described technologies, the gap with between the susceptor and the preheat ring may be controlled to control a temperature of the reactive gas, and the thickness of the thin film may be controlled according to the temperature of the reactive gas. However, there is a limitation in that it is difficult to precisely control the temperature of the flowing reactive gas, and thus, the thickness of the thin film is not precisely controlled.

### SUMMARY

Objects of embodiments are to solve the above-described limitations and other limitations.

Embodiments also provide a susceptor for epitaxial growth, which is capable of forming a thin film having an uniform thickness through upper temperature uniformization of a wafer, and an epitaxial growth apparatus including the same.

In one embodiment, a susceptor for an epitaxial growth apparatus includes: a body provided with a pocket, in which a wafer is seated, on a top surface thereof; and a temperature control plate seated in the pocket and having a plate shape in which the wafer is supported on a top surface thereof, wherein the temperature control plate has a plurality of hollows.

The hollows may include a plurality of grooves or plurality of holes, which are defined in a top or bottom surface of the temperature control plate.

The temperature control plate may be configured to have different volumes per unit area.

The grooves may be defined so that at least one or more of widths and depths of the grooves are different.

The holes may be defined so that at least one or more of diameters and the number of holes defined in a predetermined area are different.

The temperature control plate may be configured to be interlocked with a thickness profile of the thin film.

Each of the hollows may be defined at a point at which a thickness of the thin film is changed.

The temperature control plate may be provided in one of convex, concave, and flat shapes when viewed from a side.

The temperature control plate may be made of the same material as the body or be made of a material of which a thermal expansion coefficient is proportional to that of the material of the body.

In another embodiment, an epitaxial growth apparatus includes: a chamber which is configured to provide a high-temperature environment and in which a reactive gas flows; a rotational shaft rotatably provided within the chamber; a supporter provided on an upper end of the rotational shaft; and the above-described susceptor, which is supported by the supporter and on which a wafer is seated.

The details of one or more embodiments are set forth in the accompanying drawings and the description below. Other features will be apparent from the description and drawings, and from the claims.

### BRIEF DESCRIPTION OF THE DRAWINGS

FIG. 1 is a side view illustrating a support structure of a susceptor for epitaxial growth according to a related art.

FIG. 2 is a graph illustrating a change in thickness of a thin film depending on a growth temperature of the thin film during an epitaxial growth process according to the related art.

FIG. 3 is a graph illustrating a change in thickness of the thin film within a radius of the wafer during the epitaxial growth process according to the related art.

FIG. 4 is a side cross-sectional view of a groove-type susceptor according to a first embodiment.

FIG. 5 is a side cross-sectional view of a hole-type susceptor according to a second embodiment.

FIG. 6 is a side cross-sectional view of a convex-type susceptor according to a third embodiment.

FIG. 7 is a side cross-sectional view of a concave-type susceptor according to a fourth embodiment.

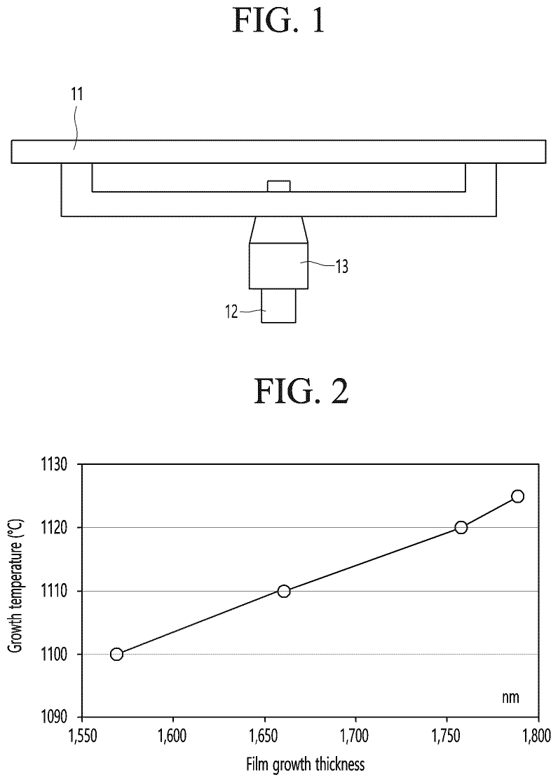

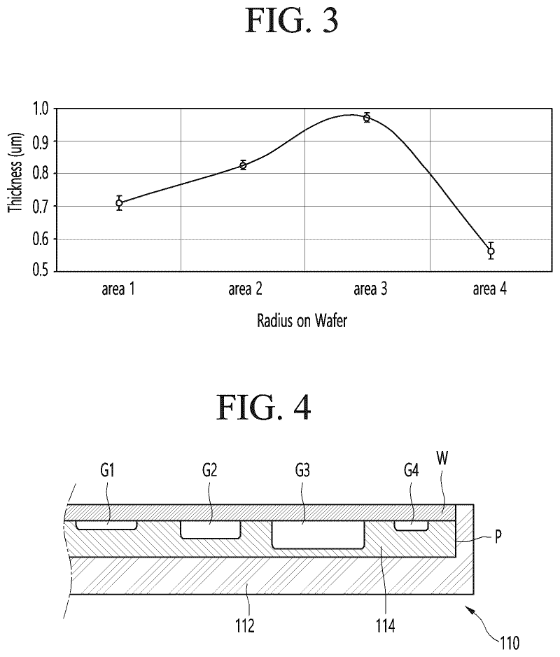

### DETAILED DESCRIPTION OF THE EMBODIMENTS

Hereinafter, exemplary embodiments will be described in detail with reference to the accompanying drawings.

FIG. 4 is a side cross-sectional view of a groove-type susceptor according to a first embodiment.

A susceptor 110 according to a first embodiment may be constituted by a body 112 provided with a pocket P in a top surface thereof, and a temperature control plate 114 seated in the pocket P. A plurality of grooves G1 to G4 may be provided in a top surface of the temperature control plate 114, and a wafer W may be seated on the top surface of the temperature control plate 114.

The body 112 may have a circular plate shape and may be provided with the pocket P, in which the temperature control plate 114 and the wafer W are seated, on the top surface thereof. The pocket P may have a depth that is deeper than a height of at least the temperature control plate 114 and a diameter that is the same as a diameter of each of the temperature control plate 114 and the wafer W. Alternatively, the shape of the pocket P may vary according to the shape of the temperature control plate 114, but is not limited thereto.

The temperature control plate 114 may have a circular plate shape and may have the grooves G1 to G4 in the top surface thereof. At least one or more of widths and depths of the grooves G1 to G4 provided in a radial direction of the temperature control plate 114 may be defined to be different, and each of the grooves G1 to G4 may be defined at a point at which the thickness of the thin film is changed in a radial direction of the wafer W in consideration of a thickness profile of the thin film disposed on the top surface of the wafer W, but is not limited thereto.

When a size and position of each of the grooves G1 to G4 in the temperature control plate 114 are configured in various manners, even though a plurality of heaters (not shown) disposed above and below the susceptor 110 heat the susceptor 110, since the temperature control plate 114 has different volumes per unit area due to the grooves G1 to G4, the susceptor 110 together with the heaters (not shown) may control thermal energy supplied to the wafer W in the radial direction, and a contact area between the temperature control plate 114 and the wafer W may be controlled to control an amount of heat transferred to the wafer W by the susceptor 110 in the radial direction. Thus, the temperature of the top surface of the wafer W may be uniform, and the thickness of the thin film disposed on the top surface of the wafer W may be uniform.

The body 112 and the temperature control plate 114 may be separately manufactured, but may be made of a material having the same thermal expansion coefficient or different materials having proportional thermal expansion coefficients. The grooves G1 to G4 may be processed separately in the temperature control plate 114, and then, the temperature control plate 114 may be detachably mounted on the body 112.

Since the temperature control plate 114 is separately manufactured, costs may be reduced compared to processing of the entire susceptor 110, and since the susceptor 110, on which the temperature control plate 114 is mounted on the body 112, is not changed in its shape as a whole, a change in airflow such as the reactive gas, etc., within a process chamber may be prevented to stably operate the process, and a heat transfer amount of the susceptor 110 may be changed simply by replacing the temperature control plate 114 to quickly respond to the change in process.

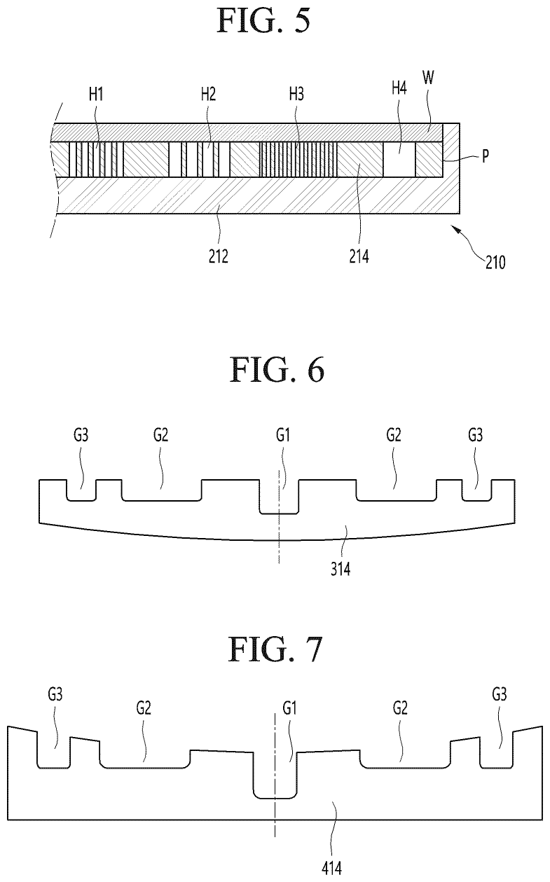

FIG. 5 is a side cross-sectional view of a hole-type susceptor according to a second embodiment.

A susceptor 210 according to a second embodiment may be constituted by a body 212 and a temperature control plate 214, like those according to the first embodiment. A plurality of holes H1 to H4 may be provided to pass through top and bottom surfaces of the temperature control plate 214, and a wafer W may be seated on the top surface of the temperature control plate 214.

Since the configurations of the body 212 and the temperature control plate 214 are the same as those according to the first embodiment, detailed descriptions will be omitted.

At least one or more of diameters and the number per unit area (density of holes in the temperature control plate) of the holes H1 to H4 provided in a radial direction of the temperature control plate 214 may be defined to be different, and each of the holes H1 to H4 may be defined at a point at which a thickness of a thin film is changed in a radial direction of the wafer W in consideration of a thickness profile of the thin film disposed on the top surface of the wafer W, but is not limited thereto.

In the susceptor 210 according to the second embodiment, a size and position of each of the holes H1 to H4 may vary in the temperature control plate 214 to control an amount of heat transferred to the wafer W by the susceptor 210 in the radial direction, like the first embodiment. Thus, a temperature of a top surface of the wafer W may be uniform, and a thickness of the thin film disposed on the top surface of the wafer W may be uniform.

FIG. 6 is a side cross-sectional view of a convex-type susceptor according to a third embodiment.

According to a susceptor according to a third embodiment, when viewed from a side of a temperature control plate 314, a top surface of the temperature control plate 314 may be flat, and also, a bottom surface of the temperature control plate 34 may be provided in convex shape. In addition, a plurality of grooves G1 to G4 may be defined with different sizes in a radial direction in the top surface of the temperature control plate 314.

Alternatively, a shape of a pocket of a body (not shown), on which the temperature control plate 314 is seated, may also be provided in the same as a shape of the convex bottom surface of the temperature control plate 314. In addition, a size and position of each of the grooves G1 to G4 may be configured in various manners in the temperature control plate 314.

The bottom surface of the temperature control plate 314 may be manufactured in the convex shape in consideration of characteristics of a material that is deformed under a high temperature at which a thin film is grown, and the temperature control plate 314 having the above-described shape may control an amount of heat to be transferred according to the position of the wafer.

Even though there is no deformation of the material under the high temperature, when the bottom surface of the temperature control plate 314 is manufactured in a convex shape, a volume at a center of the temperature control plate 314 may be greater than a volume at an edge of the temperature control plate 314, and a width and depth of each of the grooves G1 to G4 defined in the top surface of the temperature control plate 314 may be configured in various manners, and thus, a volume per unit area of the temperature control plate 314 may be configured in a more diverse manner.

In the susceptor according to the third embodiment, the bottom surface of the temperature control plate 314 may be provided in the convex shape in consideration of a change in material under the high temperature, and the grooves G1 to G4 having various sizes may be defined in the top surface of the temperature control plate 314 to provide the same effect as that according to the first embodiment, and a detailed description thereof will be omitted.

FIG. 7 is a side cross-sectional view of a concave-type susceptor according to a fourth embodiment.

According to a susceptor according to a fourth embodiment, when viewed from a side of a temperature control plate 414, a top surface of the temperature control plate 414 may be concave, and also, a bottom surface of the temperature control plate 414 may be provided in flat shape. In addition, a plurality of grooves G1 to G4 may be defined with different sizes in a radial direction in the top surface of the temperature control plate 414.

The bottom surface of the temperature control plate 414 may be manufactured in the concave shape in consideration of characteristics of a material that is deformed under a high temperature at which a thin film is grown, and the temperature control plate 414 having the above-described shape may control an amount of heat to be transferred according to the position of the wafer.

In the susceptor according to the fourth embodiment, the bottom surface of the temperature control plate 414 may be provided in the concave shape in consideration of a change in material under the high temperature, and the grooves G1 to G4 having various sizes may be defined in the top surface of the temperature control plate 414 to provide the same effect as that according to the first embodiment, and a detailed description thereof will be omitted.

According to the embodiments, the susceptor may be constituted by the body and the temperature control plate, and the hollows having the plurality of groove or hole shapes may be provided in the temperature control plate in various manners, and thus, the contact area with the temperature control plate that supports the wafer may be configured differently.

Therefore, since the thermal energy transferred to the wafer by the susceptor together with the heaters is uniformly provided in the radial direction, there may be the advantage in that the upper temperature of the wafer supported on the susceptor is uniformly provided in the radial direction, and the thickness of the thin film grown on the top surface of the wafer is uniformly maintained.

In addition, since the grooves or holes are processed into the temperature control plate, and then the temperature control plate is mounted on the body to constitute the susceptor, the processing costs may be reduced, and the overall shape of the susceptor may not be changed to prevent the airflow within the process chamber from being changed, thereby stably operating the process, and also, the heat transfer amount of the susceptor may be changed simply by replacing the temperature control plate to quickly respond to the change in process.

Those skilled in the present invention will be able to make various modifications and variations without departing from the essential characteristics of the present invention.

Thus, the embodiment of the present invention is to be considered illustrative, and not restrictive, and the technical spirit of the present invention is not limited to the foregoing embodiment.

Therefore, the scope of the present invention is defined not by the detailed description of the invention but by the appended claims, and all differences within the scope will be construed as being included in the present invention.

What is claimed is:

1. A susceptor for an epitaxial growth apparatus, comprising:
a body provided with a pocket, in which a wafer is seated, on a top surface thereof; and
a temperature control plate seated in the pocket and having a plate shape in which the wafer is supported on a top surface thereof,
wherein the temperature control plate has a plurality of hollows.

2. The susceptor according to claim 1, wherein the hollows comprise a plurality of grooves or plurality of holes, which are defined in a top or bottom surface of the temperature control plate.

3. The susceptor according to claim 2, wherein the temperature control plate is configured to have different volumes per unit area.

4. The susceptor according to claim 3, wherein the grooves are defined so that at least one or more of widths and depths of the grooves are different.

5. The susceptor according to claim 3, wherein the holes are defined so that at least one or more of diameters and the number of holes defined in a predetermined area are different.

6. The susceptor according to claim 1, wherein the temperature control plate is configured to be interlocked with a thickness profile of the thin film.

7. The susceptor according to claim 6, wherein each of the hollows is defined at a point at which a thickness of the thin film is changed.

8. The susceptor according to claim 1, wherein the temperature control plate is provided in one of convex, concave, and flat shapes when viewed from a side.

9. The susceptor according to claim 1, wherein the temperature control plate is made of the same material as the body or is made of a material of which a thermal expansion coefficient is proportional to that of the material of the body.

10. An epitaxial growth apparatus comprising:
a chamber which is configured to provide a high-temperature environment and in which a reactive gas flows;
a rotational shaft rotatably provided within the chamber;
a supporter provided on an upper end of the rotational shaft; and
the susceptor according to claim 1, which is supported by the supporter and on which a wafer is seated.
